(19) United States
(12) Patent Application Publication
(10) Pub. No.: US 2016/0087556 A1
(43) Pub. Date: Mar. 24, 2016

(54) FLUIDIC ENERGY HARVESTER USING ACTIVE MATERIAL

(71) Applicant: Research Foundation of the City University of New York, New York, NY (US)

(72) Inventors: Yiannis Andreopoulos, Orangebury, NY (US); Niell Elvin, New York, NY (US); Oleg Goushcha, New York, NY (US)

(21) Appl. No.: 14/790,558

(22) Filed: Jul. 2, 2015

Related U.S. Application Data
(60) Provisional application No. 62/054,783, filed on Sep. 24, 2014.

(51) Int. Cl. H02N 2/18; F24F 12/00; H01L 41/113

(52) U.S. Cl. CPC H02N 2/185; H01L 41/1136; F24F 12/00

(57) ABSTRACT

An array of energy harvesting units is disclosed. Each unit has a flexible, elongated support with the proximate end fixedly connected to a stationary support such that the flexible beam experiences a mechanical vibration due to flow of a fluid. An active material is disposed on the flexible support that generates an electric current in response to the mechanical vibration. A coupler is provided on each energy harvesting unit such that each is connected to at least one adjacent unit. The resulting array provides an energy output that is greater than the sum of two, uncoupled units.

### CROSS-REFERENCE TO RELATED APPLICATIONS

This application claims priority to U.S. Patent Application Ser. No. 62/054,783 (filed Sep. 24, 2014) the entirety of which is incorporated herein by reference.

### STATEMENT OF FEDERALLY SPONSORED RESEARCH OR DEVELOPMENT

This invention was made with Government support under Contract number CBET 1033117 awarded by the National Science Foundation. The Government has certain rights in the invention.

### BACKGROUND OF THE INVENTION

The subject matter disclosed herein relates to heating, ventilating and air conditioning (HVAC) systems. Conventional HVAC systems utilize components that are electrically powered. Examples of components include sensors to sense fluid flow rate and fluid temperature, actuators to alter or stop the flow of the fluid and controllers for operating and receiving data from the sensors and actuators. Each of these components needs a source of electrical power (e.g. power cords and/or batteries) which complicates the HVAC system. An improved powering system for these components is therefore desired.

The discussion above is merely provided for general background information and is not intended to be used as an aid in determining the scope of the claimed subject matter.

### BRIEF DESCRIPTION OF THE INVENTION

An array of energy harvesting units is disclosed. Each unit has a flexible, elongated support with the proximate end fixedly connected to a stationary support such that the flexible beam experiences a mechanical vibration due to flow of a fluid. An active material is disposed on the flexible support that generates an electric current in response to the mechanical vibration. A coupler is provided on each energy harvesting unit such that each is connected to at least one adjacent unit. The resulting array provides an energy output that is greater than the sum of two, uncoupled units.

In a first embodiment, a fluidic energy harvesting system is disclosed. The fluidic energy harvesting system comprises an array of energy harvesting units, each comprising a flexible, elongated support with a proximate end and a distal end, the proximate end fixedly connected to a stationary support such that the flexible, elongated support experiences a mechanical vibration due to flow of a fluid over the flexible, elongated support; an active material disposed on the flexible, elongated support, the active material generating an electric current in response to the mechanical vibration; a means for coupling on each energy harvesting unit in the array of energy harvesting units such that each energy harvesting unit is connected to at least one adjacent energy harvesting unit by the means for coupling; and an electrical connection between the array of energy harvesting unit and an electrical device such that the electrical device receives electrical power from the array of energy harvesting units.

In a second embodiment, a heating, ventilating and air conditioning (HVAC) system is disclosed. The HVAC system comprises an array of energy harvesting units, each comprising a flexible, elongated support with a proximate end and a distal end, the proximate end fixedly connected to a stationary support such that the flexible, elongated support experiences a mechanical vibration due to flow of a fluid over the flexible, elongated support; an active material disposed on the flexible, elongated support, the active material generating an electric current in response to the mechanical vibration; a means for coupling on each energy harvesting unit in the array of energy harvesting units such that each energy harvesting unit is connected to at least one adjacent energy harvesting unit by the means for coupling; an electrical connection between the array of energy harvesting unit and an electrical device such that the electrical device receives electrical power from the array of energy harvesting units; wherein the array of energy harvesting units is disposed inside of a duct of a heating, ventilating and air conditioning (HVAC) system.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of the invention. In the drawings, like numerals are used to indicate like parts throughout the various views. Thus, for further understanding of the invention, reference can be made to the following detailed description, read in connection with the drawings in which:

FIG. 1 is a schematic depiction of a heating, ventilating and air conditioning (HVAC) system;

FIG. 2 is a depiction of a single energy harvesting unit;

FIG. 3A is a depiction of an array of energy harvesting units joined at their proximate ends;

FIG. 3B is a depiction of an array of energy harvesting units joined along an elongated support;

FIG. 4 depicts shaped-tips with a variety of different shapes configured to interact with a fluid;

FIG. 5 A depicts an energy production profile for a single energy harvesting unit;

FIG. 5B depicts an energy production profile for an array of energy harvesting units;

FIG. 6 depicts an operating envelope for three energy harvesting systems;

FIG. 7A is graph depicting power harvested as a function of flow speed in smooth flow for both a single harvester and an array of harvesters; and

FIG. 7B is a graph depicting power harvested as a function of flow speed in turbulent flow for both a single harvester and an array of harvesters.

### DETAILED DESCRIPTION OF THE INVENTION

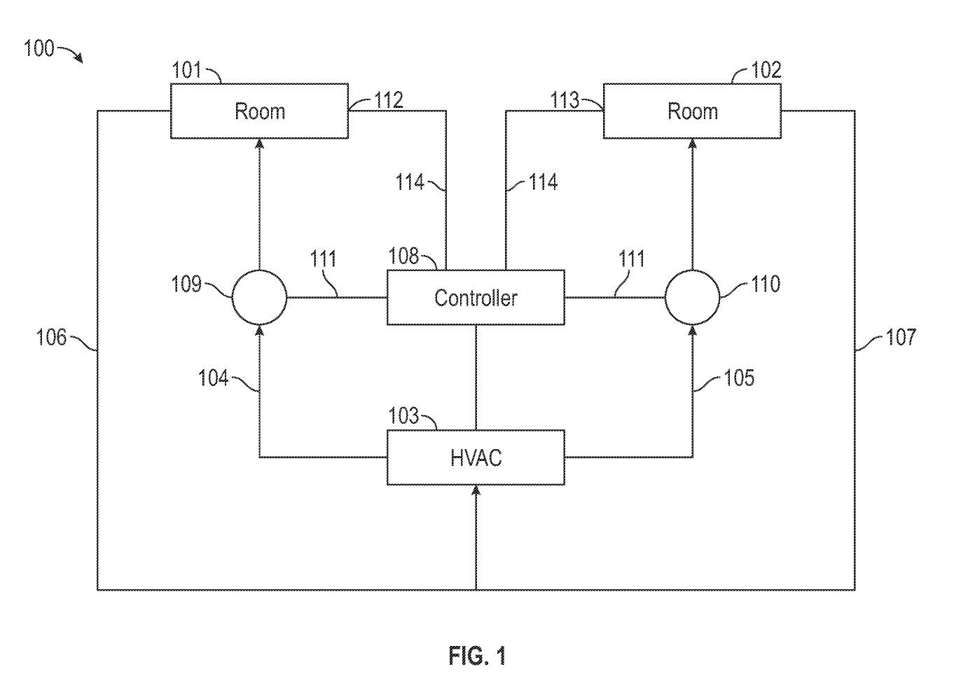

FIG. 1 depicts a HVAC system 100 that comprises a first room 101 and a second room 102, each of which are connected to a HVAC unit 103 by respective first and second fluid supply ducts 104 and 105. First and second return ducts 106 and 107 supply a return path. As used in this specification, the term “fluid” refers to both liquids and gases. A controller 108 operates first and second actuators 109, 110 through electrical wires 111. The first and second actuators 109, 110 are in-line with respect to the first and second fluid supply ducts 104, 105 such that the controller 108 can selectively control fluid flow into either the first room 101 or the second room 102. The HVAC system 100 also comprises first sensor 112 and second sensor 113 in the first and second rooms 101, 102, respectively. In the embodiment depicted in FIG. 1, the first and second sensors 112, 113 are temperature sensors that relay temperature data to the controller 108 through electrical wires 114. The controller 108 is configured to selectively control the first and second actuators 109, 110 based on the temperature data to maintain a predetermined temperature in the first and second rooms 101, 102.

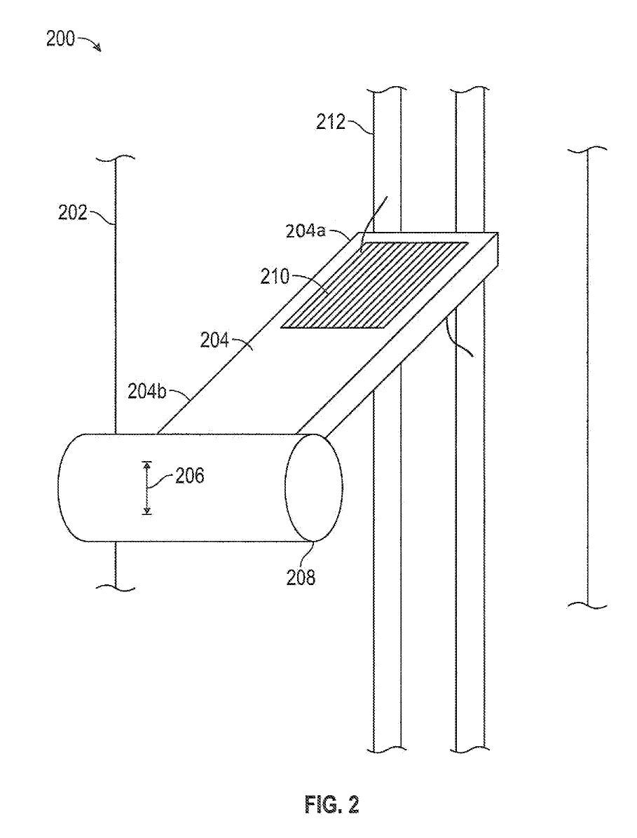

In use, the controller(s), actuator(s) and sensor(s) in many HVAC systems are electrically powered, often by batteries that must be periodically replaced. FIG. 2 depicts an energy harvesting unit that replaces the batteries in an HVAC system or permits existing batteries to be recharged. The energy harvesting refers to the harvesting of electrical energy from a fluid-electric energy conversion.

FIG. 2 depicts a single energy harvesting unit 200 that may be disposed in ducts of an HVAC system, such as first and second fluid supply ducts 104, 105 and/or first and second return ducts 106 and 107. In the example of FIG. 2, the single energy harvesting unit 200 is mounted to a stationary support 202 of a supply duct. Examples of stationary supports include a wall, floor or ceiling of a duct or a mechanical clamp with stand. The single energy harvesting unit 200 comprises an elongated support 204 with a proximate end 204a and a distal end 204b. The proximate end 204a is fixedly attached to the stationary support 202. The elongated support 204 is flexible such that the distal end 204b will oscillate in the direction of arrow 206 as fluid (e.g. air or liquid) moves through the duct. The distal end 204b has a shaped-tip 208 that interacts with the fluid. The single energy harvesting unit 200 comprises an active material 210 (e.g. piezoelectric material) on the elongated support 204. Active materials are materials that convert mechanical energy into electrical energy or the reverse operation. The active material may be, for example, polyvinylidene fluoride, lead zirconium titanate, and the like. In one embodiment, the active material is disposed on a surface of the elongated support 204 such that at least 10% of the surface of the elongated support 204 is covered on one or both sides. The oscillations deform the active material 210 and produce an electrical current that may be accessed with electrical wires 212. The electrical current may be connected to an HVAC component, such as a controller, actuator or sensor and/or recharge a power storage unit that operates a controller, actuator or sensor. Power on the order of 0.01 mW to 1 W can be supplied. The elongated support 204 functions as a cantilever and may be formed from any suitably flexible material such as aluminum, polyethylene terephthalate (e.g. mylar), composite material and the like. The thickness of the elongated support is controlled to provide flexibility while the length is controlled to alter the magnitude of oscillations. Examples of suitable thicknesses are between 0.5 mm and 3 mm. Examples of suitable lengths are between 2 cm and 100 cm.

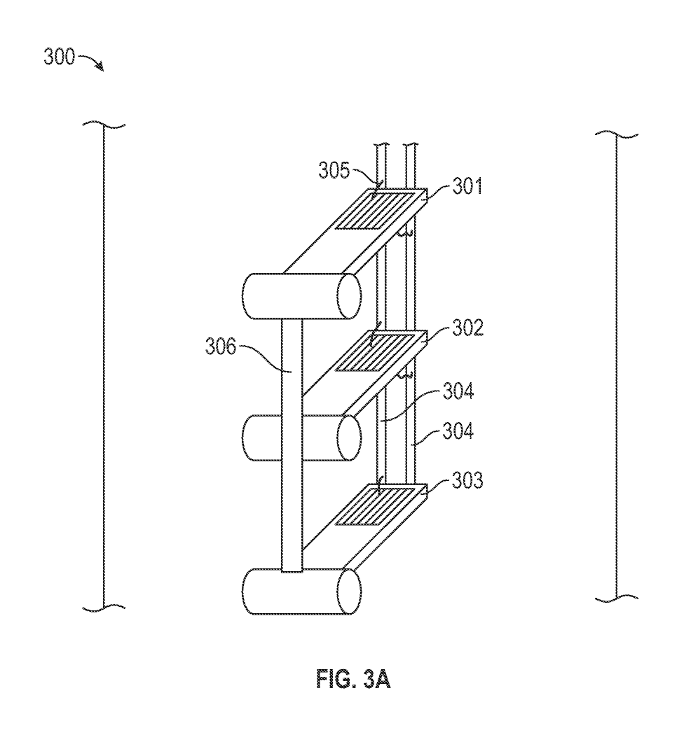

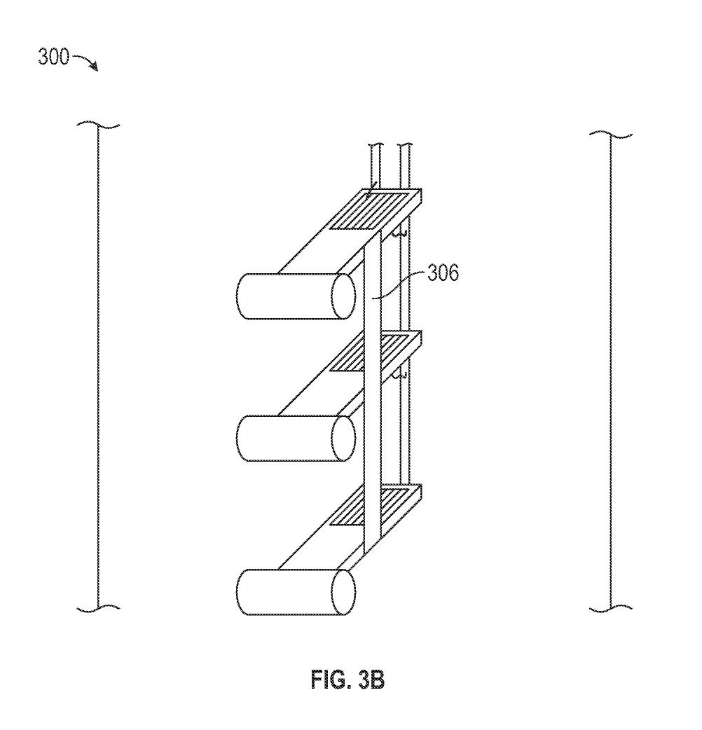

FIG. 3A depicts an array 300 that comprises multiple energy harvesting units 301, 302, 303. In FIG. 3A, each energy harvesting unit in the array 300 is connected by electrical connections 304. Each active material may be connected to the electrical connections 304 by leads 305. By connecting multiple energy harvesting units, additional power can be produced.

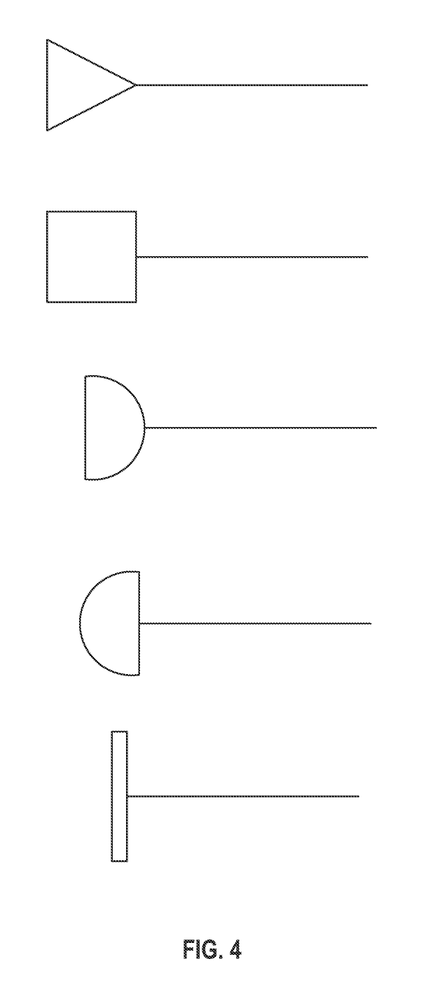

Each energy harvesting unit is connected to at least one adjacent energy harvesting unit at a respective shaped-tip (see FIG. 3A) or the elongated beam (see FIG. 3B) by a means for coupling 306. Examples of means for coupling include elastic connectors such as springs, elastomeric bands, magnets, and the like. Generally, moving the means for coupling 306 toward the distal end 204b results is a less rigid system that is suitable for slow fluid velocities. Conversely, moving the means for coupling 306 toward the proximate end 204a results in a more rigid system that is suitable for faster fluid velocities. The shaped-tip 208 may have a variety of different shapes configured to interact with the fluid. In the embodiment of FIGS. 2, 3A and 3B, the shape is cylindrical. In other embodiment, the shape may be a rectangular tube, a half-cylinder, a pyramid, a flat plate and the like. See FIG. 4. Without wishing to be bound to any particular theory, the natural vortices in the fluid interact with the shape to produce a particular fluid current. By altering the shape, an acceptable oscillation can be achieved while providing the ability to place the energy harvesting unit in any orientation relative to the direction of fluid flow. In one embodiment, the elongated support 204 has a longitudinal axis that extends parallel to the direction of fluid flow with the shaped-tip 208 being disposed upstream.

The shaped-tip 208 of the distal end 204b may be at least about 20% of the total mass of the energy harvesting unit. In another embodiment, the shaped-tip 208 is about 50% of the total mass. Generally, as the mass of the shaped-tip increases, the power output decreases while the oscillations become more sustained. Accordingly, the oscillation sustainability and power output are balanced against one another to achieve a desired outcome.

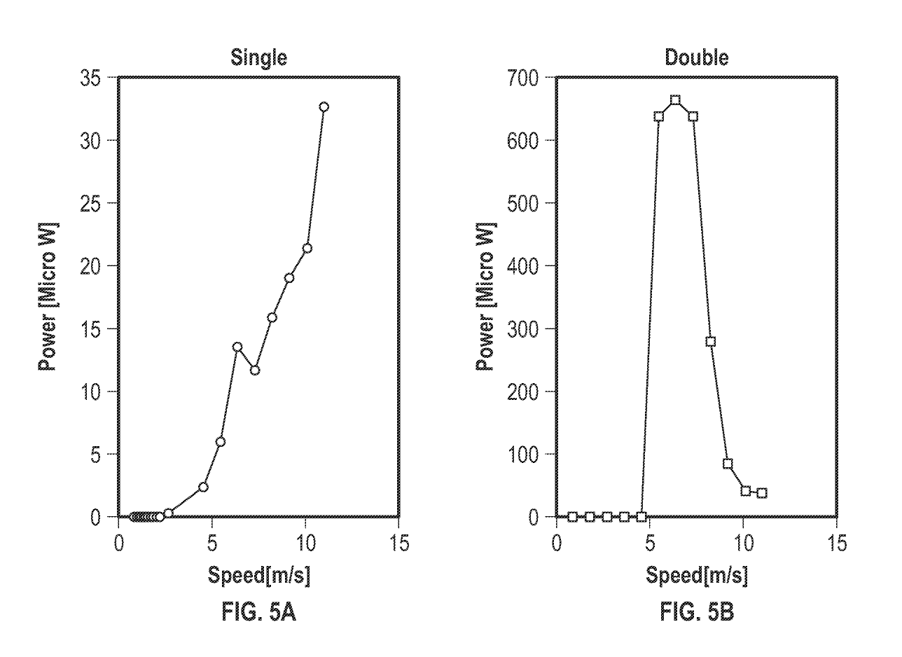

FIG. 5A and FIG. 5B depict flow speed versus power harvested in a turbulent flow for two different example systems. FIG. 5A depicts an energy production profile for a single energy harvesting unit with a maximum of less than 35 microW. FIG. 5B depicts an energy production profile for two energy harvesting units that are connected in an array. The array of two energy production units shows a maximum of just under 700 microW. Each energy harvesting unit in an array interacts nonlinearly with adjacent energy harvesting units such that a response is greater than twice the response of a single energy harvesting unit.

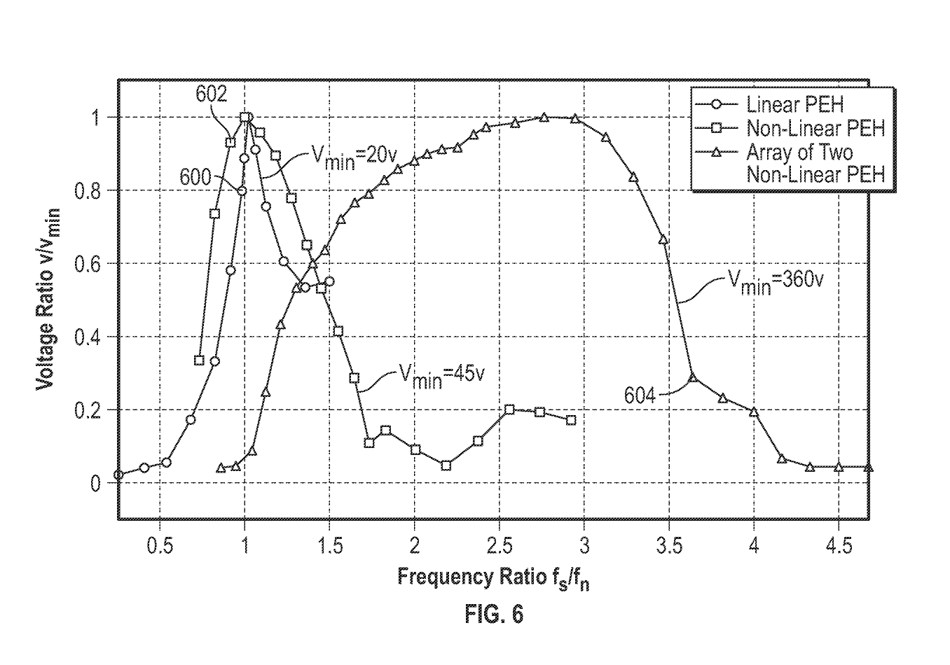

FIG. 6 depicts an operating envelope for three energy harvesting systems. The Y axis is the ratio of voltage output (V) to maximum voltage output (Vₘₐₓ). The X axis is the ratio of the flow frequency (fₛ) (defined as the speed of the flow divided by a length scale in this case a diameter of the tip mass) to the natural frequency of the harvester defined by its first mode of vibration frequency (fₙ). Line 600 shows a linear PEH (Piezo-Electric Harvester) that has a single energy harvesting unit without a shaped-tip experiencing small linear deflections. Line 602 shows a non-linear PEH that has a single energy harvesting unit with a shaped-tip experiencing large non-linear deformations. The linear and non-linear PEH were tested separately. Line 604 shows two harvesters positioned together in an array. Line 604 has a wider “operating envelope” where voltage is produced so the system can harvest energy from wider range of flow velocities. Because the operating envelope is large and the array configuration can accommodate the fluctuating speeds in the turbulent flow, the power production is large in an array configuration.

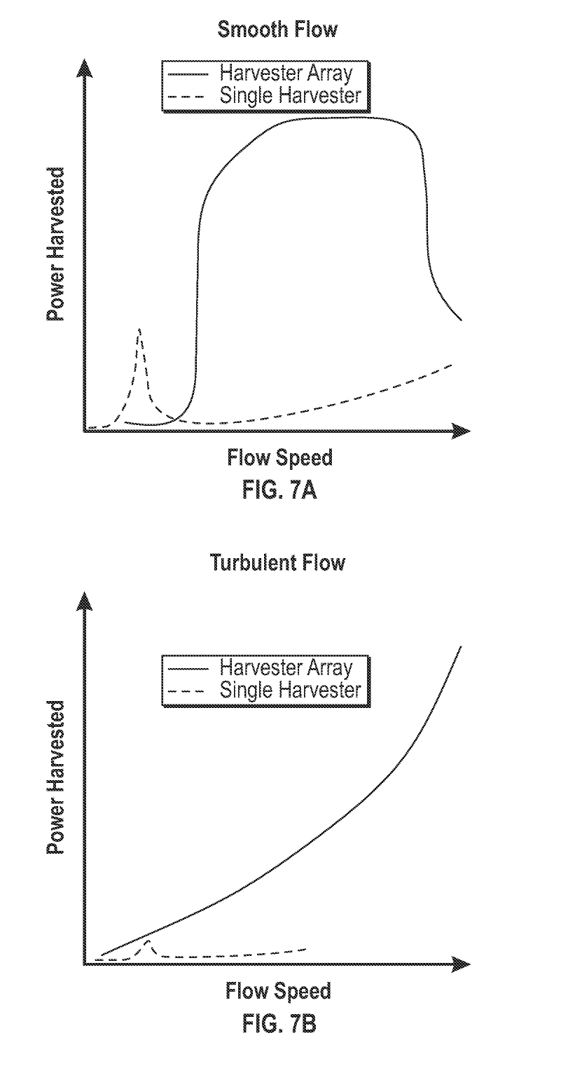

FIG. 7A and FIG. 7B graphically depict the improved power harvesting from an array of energy harvesting units in comparison to a single energy harvesting unit. At smooth flow (FIG. 7A) the operating envelope of an array of energy harvesting units is wider than the operating envelope for a single energy harvesting unit. At turbulent flow (FIG. 7B) the operating envelope of an array of energy harvesting units is also wider although the profile of the curve has changed.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A fluidic energy harvesting system comprising:
an array of energy harvesting units, each comprising:
a flexible, elongated support with a proximate end and a distal end, the proximate end fixedly connected to a stationary support such that the flexible, elongated support experiences a mechanical vibration due to flow of a fluid over the flexible, elongated support;
an active material disposed on the flexible, elongated support, the active material generating an electric current in response to the mechanical vibration;
a means for coupling on each energy harvesting unit in the array of energy harvesting units such that each energy harvesting unit is connected to at least one adjacent energy harvesting unit by the means for coupling;
an electrical connection between the array of energy harvesting unit and an electrical device such that the electrical device receives electrical power from the array of energy harvesting units.

2. The system as recited in claim 1, wherein the electrical device is selected from the group consisting of a sensor, an actuator and a controller.

3. The system as recited in claim 1, wherein the fluid is air.

4. The system as recited in claim 1, wherein the fluid is water.

5. The system as recited in claim 1, wherein the distal end has a shaped-tip.

6. The system as recited in claim 1, wherein the distal end has a shaped-tip with a shape selected from the group consisting of a rectangular tube, a half-cylinder, a pyramid, a flat plate.

7. The system as recited in claim 1, wherein the means for coupling is an elastic connector.

8. The system as recited in claim 1, wherein the means for coupling is a spring.

9. The system as recited in claim 1, wherein the means for coupling is an elastomeric band.

10. The system as recited in claim 1, wherein the means for coupling is a magnet.

11. The system as recited in claim 1, wherein the array of energy harvesting units consists of two energy harvesting units.

12. The system as recited in claim 1, wherein the array of energy harvesting units comprises at least three energy harvesting units.

13. A heating, ventilating and air conditioning (HVAC) system comprising:
an array of energy harvesting units, each comprising:
a flexible, elongated support with a proximate end and a distal end, the proximate end fixedly connected to a stationary support such that the flexible, elongated support experiences a mechanical vibration due to flow of a fluid over the flexible, elongated support;
an active material disposed on the flexible, elongated support, the active material generating an electric current in response to the mechanical vibration;
a means for coupling on each energy harvesting unit in the array of energy harvesting units such that each energy harvesting unit is connected to at least one adjacent energy harvesting unit by the means for coupling;
an electrical connection between the array of energy harvesting unit and an electrical device such that the electrical device receives electrical power from the array of energy harvesting units;
wherein the array of energy harvesting units is disposed inside of a duct of a heating, ventilating and air conditioning (HVAC) system.

14. The system as recited in claim 13, wherein the electrical device is selected from the group consisting of a sensor, an actuator and a controller.

15. The system as recited in claim 13, wherein the array of energy harvesting units consists of two energy harvesting units.

16. The system as recited in claim 13, wherein the array of energy harvesting units comprises at least three energy harvesting units.

17. The system as recited in claim 13, wherein the distal end has a shaped-tip.

18. The system as recited in claim 17, wherein the distal end has a shaped-tip with a shape selected from the group consisting of a rectangular tube, a half-cylinder, a pyramid, a flat plate.
